(19) United States
(12) Patent Application Publication
(10) Pub. No.: US 2006/0039103 A1
(43) Pub. Date: Feb. 23, 2006

(54) Hinge assembly and disc player having the same

(75) Inventors: He-Li Wang, Shenzhen (CN); Huang-Chin Liao, Tu-Cheng (TW); Wen-Jie Bao, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry Co., LTD., Tu-Cheng City (TW)

(21) Appl. No.: 11/204,657

(22) Filed: Aug. 16, 2005

(30) Foreign Application Priority Data
Aug. 19, 2004 (CN) 200420083273.9

(51) Int. Cl. H05K 5/00

(52) U.S. Cl. 361/679

(57) ABSTRACT

A hinge assembly for a disc player includes a housing having a shaft-receiving portion and a lid. The hinge assembly includes at least one supporting portion secured to the lid and at least one torsional spring surrounding the second portion. The supporting portion includes a shaft formed thereon, and a hole defined therein. The shaft includes a first portion coupled to the shaft-receiving portion and an opposite second portion. The torsional spring includes first and second ends, the first ends being coupled to the housing, the second ends thereof being engaged in the hole of the supporting portion. A disc player incorporating said hinge assembly is also provided.

### BACKGROUND

1. Field of the Invention

The present invention is related to disc players, and particularly to a hinge assembly and a disc player incorporating the hinge assembly.

2. Related Art

Generally, disc players can be divided into three types: a tray disc type, a caddy type, and a lid type. A conventional lid-type disc player generally includes a housing, and a lid connected to the housing via a hinge assembly. The hinge assembly is for opening up or closing the lid of the disc player. The hinge assembly generally can drive the lid to move between a closed position and an open position.

However, the above-mentioned conventional hinge assembly of the disc player has some deficiencies and inadequacies. Firstly, the lid is generally popped up to the open position rather quickly. The lid is thus liable to wobble or even be damaged due to the sudden strong force acting on the lid. Secondly, in the case of the disc player having a screen hinged to the housing and covering the lid, the lid may accidentally scratch or damage the screen when the lid pops up toward the open position.

Therefore, a heretofore unaddressed need exists in the industry to address the aforementioned deficiencies and inadequacies.

### SUMMARY

A hinge assembly for a disc player includes a housing having a shaft-receiving portion and a lid. The hinge assembly includes at least one supporting portion secured to the lid and at least one torsional spring surrounding the second portion. The supporting portion includes a shaft formed thereon, and a hole defined therein. The shaft includes a first portion coupled to the shaft-receiving portion and an opposite second portion. The torsional spring includes first and second ends, the first ends being coupled to the housing, the second ends thereof being engaged in the hole of the supporting portion.

A disc player includes a housing, at least one hinge, and a lid. The housing includes at least one opening, a shaft-receiving portion and a retaining portion. The shaft-receiving portion and the retaining portion being arranged at opposite side of the opening. The lid is pivotally coupled to the housing via the hinge assembly. The hinge assembly includes at least one supporting portion secured to the lid and at least one torsional spring surrounding the second portion. The supporting portion includes a shaft formed thereon, and a hole defined therein. The shaft includes a first portion coupled to the shaft-receiving portion and an opposite second portion. The torsional spring includes first and second ends, the first ends being coupled to the housing, the second ends thereof being engaged in the hole of the supporting portion.

Other systems, methods, features, and advantages will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is an exploded, isometric view of a disc player in accordance with an exemplary embodiment of the present invention, but not showing a screen thereof.

FIG. 2 is an enlarged, isometric view of a lid of the disc player of FIG. 1.

FIG. 3 is a bottom plan view of an upper cover and the lid attached thereto, of the disc player of FIG. 1.

FIG. 4 is an enlarged view of a circled portion IV of FIG. 3.

FIG. 5 is an enlarged view of a circled portion V of FIG. 3.

### DETAILED DESCRIPTION OF PREFERRED EMBODIMENTS

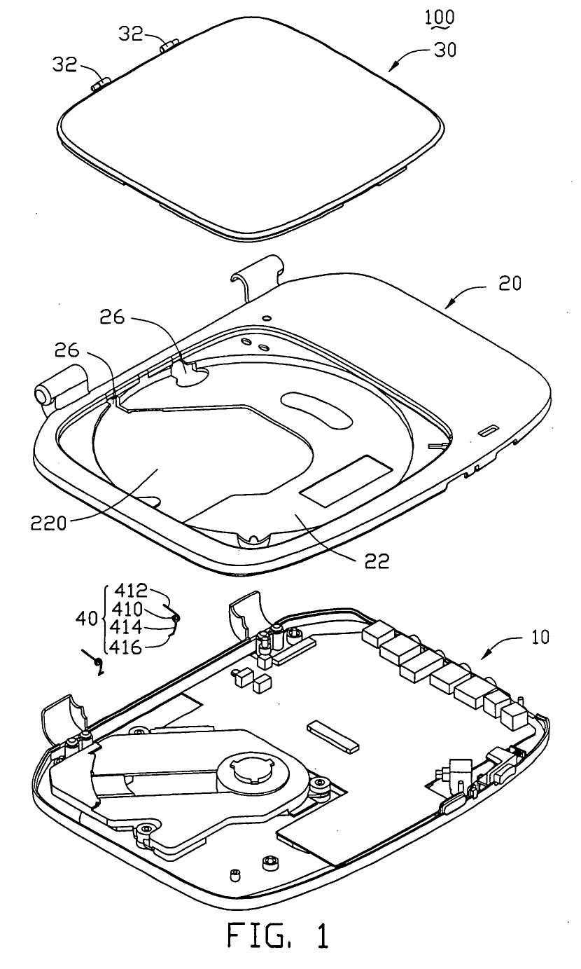

Referring to FIG. 1, a disc player 100 includes a housing comprising a lower cover 10 and an upper cover 20 hinged to the lower cover 10, a lid 30 pivotally connected with the upper cover 20, and a pair of resilient members like torsional springs 40. The lower cover 10 is completely covered by the upper cover 20, and a space (not labeled) is defined between the lower cover 10 and the upper cover 20 for accommodating various elements therein.

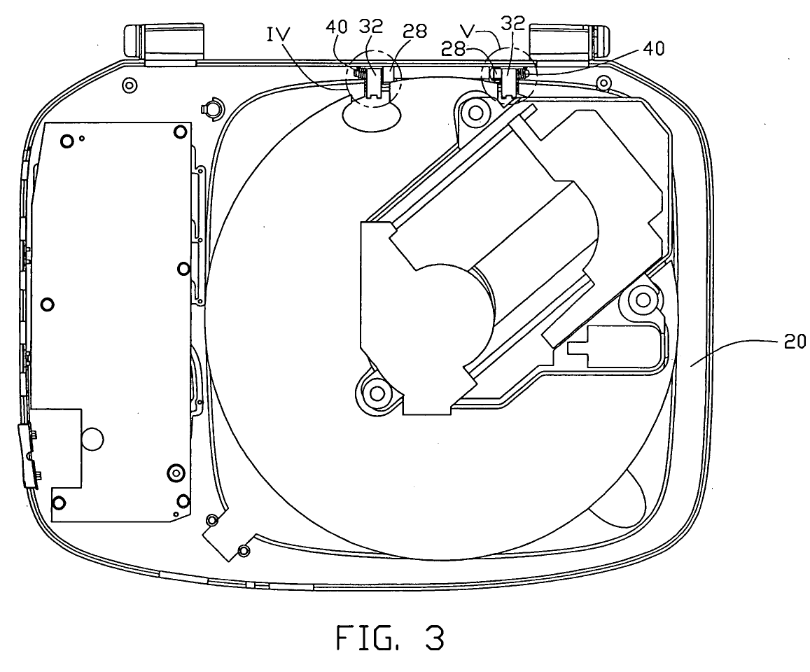

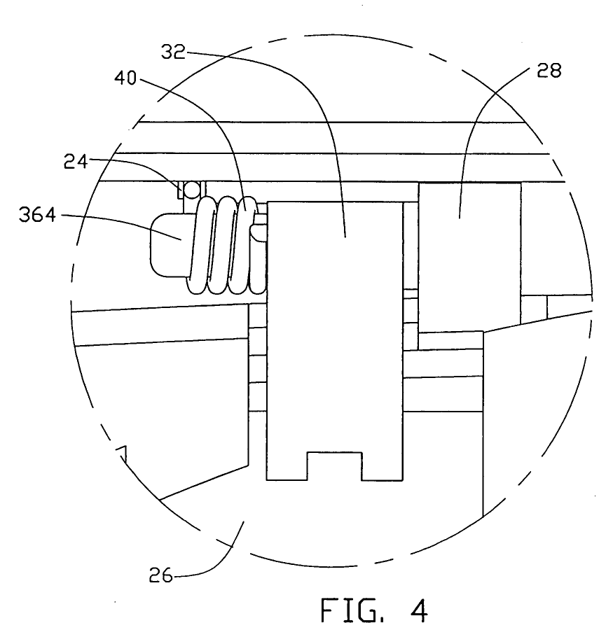

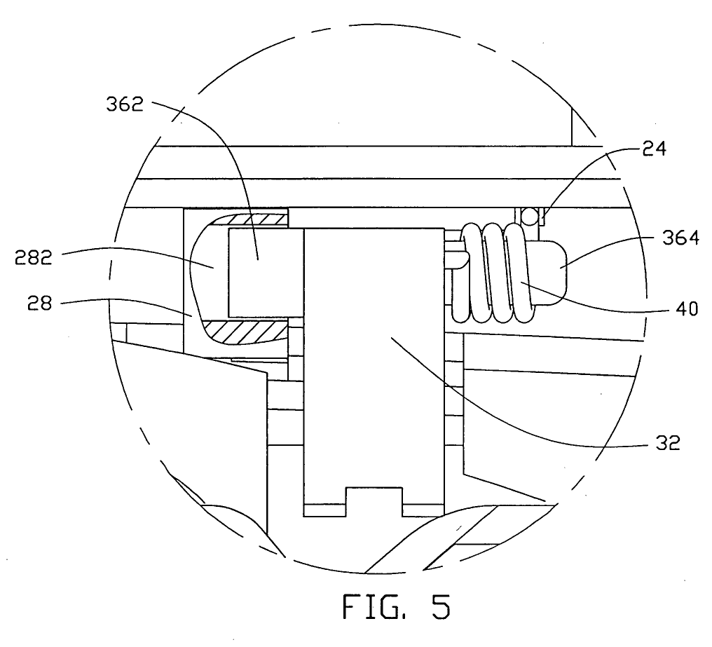

The upper cover 20 defines a disc receiving area 22 for receiving an optical disc therein. An opening 220 is defined in the disc receiving area 22, for allowing a pick-up head (not shown) to move therein so as to read information stored in the optical disc. The disc receiving area 22 is completely covered by the lid 30, for preventing the optical disc received therein from flying out when the optical disc is rotating at high speeds. The upper cover 20 defines a pair of slots 26 in an edge portion thereof. A pair of shaft-receiving portions 28 are formed on a lower surface of the upper cover 20 opposite from the disc receiving area 22 (as shown in FIG. 3). The shaft-receiving portions 28 are located adjacent inner sides of the slots 26. A pair of retaining portions 24 is respectively formed adjacent outer sides of the pair of slots 26 (as shown in FIG. 4 and FIG. 5). Each shaft-receiving portion 28 defines a receiving hole 282 (as shown in FIG. 5).

Each torsional spring 40 includes a body 410, and a first arm 412 and a second arm 414 extending from opposite ends of the body 410. A bent portion 416 is formed at a distal end of the second arm 414.

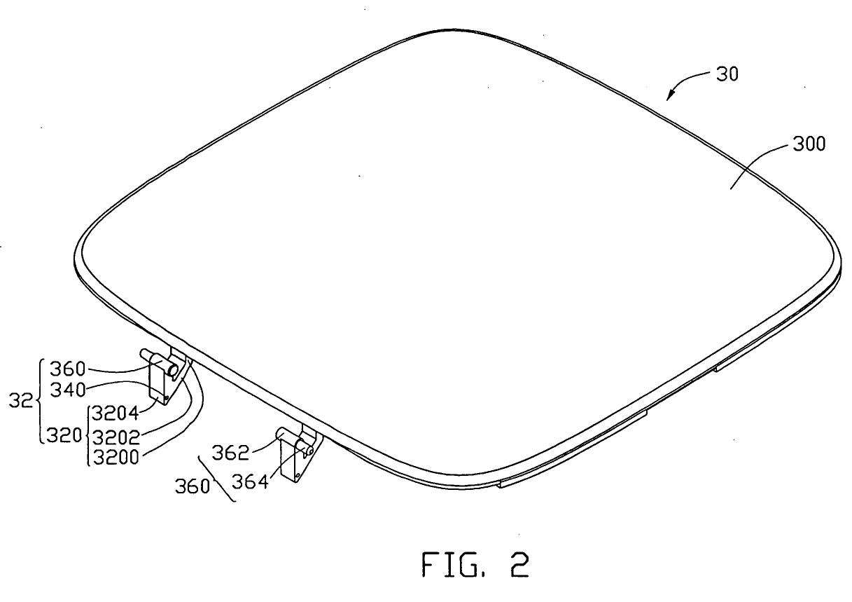

Referring to FIG. 2, the lid 30 is substantially rectangular, and includes a lid body 300, and a pair of supporting portions 32 integrally formed on an edge portion of the lid body 300 used as a hinge assembly for the disc player 100. The supporting portions 32 are respectively accommodated in the corresponding slots 26. The lid 30 is pivotably connected with the upper cover 20 via the supporting portions 32.

Each supporting portion 32 includes a base portion 320, a hole 340, and a shaft 360. The base portion 320 is substantially U-shaped, and includes a first upright portion 3200, an interconnection portion 3202, and a second upright portion 3204. The first upright portion 3200 has a first end extending from the lid 30, and an opposite second end. The second upright portion 3204 has a first end with the shaft 360 formed thereon, and an opposite second end. The interconnection portion 3202 interconnects the second end of the first upright portion 3200 and the second end of the second upright portion 3204. Each second upright portion 3204 of the supporting portions 32 has a height greater than that of the first upright portion 3200. Each hole 340 is defined at a joint portion between the interconnection portion 3202 and the second upright portion 3204, for receiving the bent portion 416 of the corresponding torsional spring 40. The shafts 360 formed on the second upright portions 3204 are substantially parallel with a main plane of the lid body 300.

In other exemplary embodiments, each base portion of the supporting portions 32 is substantially V-shaped, and includes a first portion and a second portion. In this embodiment, the first portion has a first end extending from the edge portion of the lid body 300, and an opposite second end connected to the second portion. The hole 340 is defined at the joint portion between the first portion and the second portion. The shaft 360 is formed at a distal end of the second portion 340.

Each shaft 360 includes a first portion 362 and a second portion 364. The first portions 362 of the shafts 360 extend toward each other, while the second portions 364 of the shafts 360 extend away from each other.

Referring to FIGS. 3 to 5, the first portions 362 of the shafts 360 are received in the shaft-receiving portion 282. The bodies 410 of the torsional springs 40 surround the second portions 364 of the shafts 360. The bent portions 416 of the torsional springs 40 are engaged in the holes 340. The first arms 412 of the torsional springs 40 are retained in the retaining portions 24.

When the lid 30 is in a closed position, the torsional springs 40 are twisted. To open up the disc player, the lid 30 is disengaged from the upper cover 20. This is done by pressing a controlling button (not shown), which releases a mechanical latching mechanism (not shown). The twisted torsional springs 40 then apply a torsional force to the supporting portions 32, whereby the lid 30 is rotated relative to the shafts 360 to an open position.

The torsional force acts directly on the supporting portions 32 instead of the lid body 300. The force indirectly acting on the lid 30 thus becomes moderate. Any wobbling of or damage to the lid 30 is thus avoided. When the lid 30 is in the open position, the lid 30 is supported and stationed by the supporting portions 32. Accordingly, scratching or damaging of a screen (not shown) of the disc player 100 may be avoided.

In another exemplary embodiment, the retaining portions 24 can instead be arranged between and adjacent inner sides of the slots 26; while the shaft-receiving portions 28 are arranged adjacent outer sides of slots 26, opposite from the corresponding retaining portions 24. The second portions 364 of the shafts 360 extend toward each other, while the first portions 362 of the shafts 360 extend away from each other.

The embodiments and methods described herein are merely illustrative of the principles of the present invention. Other arrangements and advantages may be devised by those skilled in the art without departing from the spirit and scope of the present invention. Accordingly, the present invention should be deemed not to be limited to the above detailed description, but rather by the spirit and scope of the claims that follow, and their equivalents.

What is claimed is:

1. A hinge assembly for a disc player including a housing having a shaft-receiving portion and a lid, the hinge assembly comprising:
at least a supporting portion secured to the lid, the supporting portion comprising a shaft formed thereon, and a hole defined therein, the shaft comprising a first portion coupled to the shaft-receiving portion and an opposite second portion; and
at least one torsional spring surrounding the second portion, the torsional spring having first and second ends, the first end being coupled to the housing, the second end thereof being engaged in the hole of the supporting portion.

2. The hinge assembly as claimed in claim 1, wherein the supporting portion further comprises a first upright portion having a first end formed on the lid and an opposite second end, an interconnection portion, a second upright portion having a first end with a shaft formed thereon and an opposite second end, the interconnection portion being formed between the second end of the first upright portion and the second end of the second upright portion.

3. The hinge assembly as claimed in claim 2, wherein the hole is defined at a joint portion between the interconnection portion and the second upright portion.

4. The hinge assembly as claimed in claim 1, wherein the supporting portion further comprises a first portion extending from the lid, and a second portion extending from the first portion.

5. The hinge assembly as claimed in claim 4, wherein the hole is defined at a joint portion between the first portion and the second portion.

6. The hinge assembly as claimed in claim 1, wherein the spring comprises a body, a first arm extending from one end of the body, a second arm extending from the other end of the body, and a bent portion formed at a distal end of the second arm.

7. The hinge assembly as claimed in claim 6, wherein the first arm of the spring is coupled to the housing, and the bent portion is engaged in the hole of the supporting portion.

8. A disc player, comprising:
a housing comprising at least one opening, a shaft-receiving portion and a retaining portion, the shaft-receiving portion and the retaining portion being arranged at opposite side of the opening;
at least one hinge assembly; and a lid pivotally coupled to the housing via the hinge assembly, the hinge assembly comprising: a supporting portion formed on the lid, the supporting portion comprising a shaft formed thereon, and a hole defined therein, the shaft comprising a first portion coupled to the shaft-receiving portion and an opposite second portion; and at least one torsional spring surrounding the second portion of the shaft, the torsional spring having first and second ends, the first end being coupled to the retaining portion of the housing, the second end being engaged in the hole of the supporting portion.

9. The disc player as claimed in claim 8, wherein the supporting portion further comprises a first upright portion having a first end formed on the lid and an opposite second end, an interconnection portion, a second upright portion having a first end with a shaft formed thereon and an opposite second end, the interconnection portion being formed between the second end of the first upright portion and the second end of the second upright portion.

10. The disc player as claimed in claim 9, wherein the hole is defined at a joint portion between the interconnection portion and the second upright portion.

11. The disc player as claimed in claim 8, wherein the supporting portion further comprises a first portion extending from the lid, and a second portion extending from the first portion.

12. The disc player as claimed in claim 11, wherein the hole is defined at a joint portion between the first portion and the second portion.

13. The disc player as claimed in claim 8, wherein the spring comprises a body, a first arm extending from one end of the body, a second arm extending from the other end of the body, and a bent portion formed at a distal end of the second arm.

14. The disc player as claimed in claim 9, wherein the first arm of the spring is coupled to the retaining portion of the housing, and the bent portion is engaged in the hole of the supporting portion.

15. A disc player comprising:
a housing enclosing one part of said player and defining a disc receiving area theron to be exposable;
a lid enclosing the other part of said player and movably attachable to said housing, said lid movable relative to said housing between a first position thereof to abut against and cover said disc receiving area of said housing, and a second position thereof to move away and expose said disc receiving area; and
a supporting portion supportively attaching said lid to said housing, said supporting portion comprising a base portion to engage with said lid, a shaft engaging with said base portion to be capable of engaging with said housing to guide movement of said lid between said first and second positions thereof, and a resilient member attachably working next to said shaft to control said movement of said lid together with said shaft, said shaft and said resilient member being significantly spaced from said lid by means of supportively engagement of said base portion with said lid and said shaft respectively.

16. The disc player as claimed in claim 15, wherein said base portion of said supporting portion is one of a U shape and a V shape integrally extending from an edge of said lid.

17. The disc player as claimed in claim 15, wherein said resilient member is a torsional spring with a first end thereof coupled to a retaining portion of said housing and a second end thereof engaging within a hole defined in said base portion far away from said lid.
